(19) United States
(12) Patent Application Publication
(10) Pub. No.: US 2026/0066226 A1
(43) Pub. Date: Mar. 5, 2026

(54) METHOD OF SUSTAINING PLASMA FOR PLASMA PROCESSING

(71) Applicant: Tokyo Electron Limited, Tokyo (JP)

(72) Inventors: Zhiying Chen, Austin, TX (US); Megan Carruth, Austin, TX (US); Joel Blakeney, Austin, TX (US); Peter Lowell George Ventzek, Austin, TX (US); Shyam Sridhar, Austin, TX (US); Mitsunori Ohata, Taiwa-cho (JP)

(21) Appl. No.: 18/819,736

(22) Filed: Aug. 29, 2024

(51) Int. Cl. H01J 37/32; H01L 21/67

(52) U.S. Cl. CPC H01J 37/32146; H01J 37/321; H01J 2237/3341

(57) ABSTRACT

A method for plasma processing a substrate includes: sustaining a plasma in a plasma processing chamber, the plasma processing chamber including a first electrode and a second electrode, where sustaining the plasma includes: coupling a source signal to the first electrode; and applying a bias signal to the second electrode, the bias signal having a spike waveform including a plurality of bias pulses, each of the bias pulses including a DC base voltage for a base duration and a triangular voltage spike having a rise time from the base voltage to a peak voltage and a fall time from the peak voltage to the base voltage, a sum of the rise time, the fall time, and the base duration including a pulse period, the applying including: independently adjusting the rise time and fall time to obtain a narrow energy spread of a mode at a high modal energy in an ion energy distribution function (IEDF) of an ion flux incident on the substrate, the narrow energy spread including a first width of the high energy mode of the IEDF that is smaller than a second width of the high energy mode of the IEDF obtainable using a rectangular pulse waveform.

### TECHNICAL FIELD

The present invention relates generally to a method for plasma processing, and, in particular embodiments, to a method of sustaining plasma for plasma processing.

### BACKGROUND

An integrated circuit (IC) is a network of electronic components connected by multiple levels of wiring formed as a monolithic structure of a semiconductor substrate. The network comprises a stack of layers that are sequentially deposited and patterned using lithography and etch processes. With advances in patterning technology, a new IC technology node is introduced about every two years, where the component density is doubled by shrinking feature sizes and using three dimensional (3D) devices, a combination that leads to fabricating very high aspect ratio structures. The fabrication methods commonly use plasma processing, such as reactive ion etching (RIE), thus challenging plasma technology to etch the high aspect ratio structures with almost atomic level control of local critical dimension uniformity (LCDU) and etch profile to achieve high manufacturing yield. For a high aspect ratio contact (HARC) etch process to meet stringent constraints on precision, uniformity, stability, and repeatability required for IC manufacturing, a strictly controlled plasma is desired. In an RIE process, vertically directed high energy ions are used to anisotropically etch an exposed surface. Not surprisingly, the etch profiles of deep trenches and holes with nanometer scale openings are sensitive to the energy and direction with which ions strike the surface. Thus, precise control of the etch profile relies on precise control of ion energy and ion angle of the ions impinging on the substrate. Accordingly, further innovation is desired toward providing an ion flux having very narrow spreads in ion energy and ion angle distributions.

### SUMMARY

A method for plasma processing a substrate includes: sustaining a plasma in a plasma processing chamber, the plasma processing chamber including a first electrode and a second electrode, where sustaining the plasma includes: coupling a source signal to the first electrode; and applying a bias signal to the second electrode, the bias signal having a spike waveform including a plurality of bias pulses, each of the bias pulses including a DC base voltage for a base duration and a triangular voltage spike having a rise time from the base voltage to a peak voltage and a fall time from the peak voltage to the base voltage, a sum of the rise time, the fall time, and the base duration including a pulse period, the applying including: independently adjusting the rise time and fall time to obtain a narrow energy spread of a mode at a high modal energy in an ion energy distribution function (IEDF) of an ion flux incident on the substrate, the narrow energy spread including a first width of the high energy mode of the IEDF that is smaller than a second width of the high energy mode of the IEDF obtainable using a rectangular pulse waveform.

A method for plasma processing a substrate includes: coupling a source signal to a first electrode of a plasma processing chamber; and applying a bias signal to a second electrode of the plasma processing chamber, the bias signal having a spike waveform including a plurality of bias pulses, each of the bias pulses including a DC base voltage for a base duration and a triangular voltage spike having a rise time from the base voltage to a peak voltage and a fall time from the peak voltage to the base voltage, a sum of the rise time, the fall time, and the base duration including a pulse period, the applying including: independently adjusting the rise time and fall time to obtain a narrow energy spread of a mode at a high modal energy in an ion energy distribution function (IEDF) of an ion flux incident on the substrate, the narrow energy spread including a first width of the high energy mode of the IEDF that is smaller than a second width of the high energy mode of the IEDF obtainable using a rectangular pulse waveform, where the plurality of bias pulses of the spike waveform includes a first plurality of first bias pulses having a first peak voltage and a second plurality of second bias pulses having a second peak voltage different from the first peak voltage.

A plasma processing apparatus including: a plasma processing chamber to sustain a plasma, the plasma processing chamber including: a first electrode configured to receive a source signal; and a second electrode configured to receive a bias signal; a controller; and a memory coupled to the controller and storing instructions to be executed in the controller, the instructions when executed by the controller cause the apparatus to: couple the source signal from a first electrical circuit to the first electrode; and apply the bias signal from a second electrical circuit to the second electrode, the bias signal having a spike waveform including a plurality of bias pulses, each of the bias pulses including a pulse period and a voltage spike having a rise time from a base voltage to a peak voltage and a fall time from the peak voltage to the base voltage, where the instructions to apply includes instructions to change an ion energy of ions towards a pedestal independently from an ion flux toward the pedestal by independently changing the peak voltage from the pulse period.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a schematic cross-sectional view of a plasma processing apparatus, in accordance with some embodiment of the invention;

FIG. 2 illustrates plots of several source signal waveforms, in accordance with some embodiment of the invention;

FIG. 3 illustrates plots of several bias signal waveforms, in accordance with some embodiment of the invention;

FIG. 4 illustrates plots comparing the ion energy distribution function (IEDF) associated with a bias signal having a pulsed DC waveform and with the IEDF associated with a bias signal having a spike waveform, in accordance with some embodiment of the invention;

FIG. 5 illustrates various plots of IEDF demonstrating the impact of changing the peak voltage of a voltage spike of the spike waveform, in accordance with some embodiments of the invention;

FIG. 6 illustrates various plots of IEDF demonstrating the impact of changing the pulse period of a bias pulse of the spike waveform, in accordance with some embodiments of the invention; and

FIGS. 7A-7H illustrate plots of various pairs of a source signal and a bias signal waveform for various plasma processing applications, in accordance with various embodiments of the invention.

### DETAILED DESCRIPTION OF ILLUSTRATIVE EMBODIMENTS

This disclosure describes a method for direct plasma processing of a semiconductor substrate by exposing a major surface of the substrate to plasma in a plasma processing chamber. The method provides an advantage of sustaining an ion flux comprising high energy ions impinging on the surface with an ion energy distribution function (IEDF) having a narrow energy spread. The narrow energy spread may be advantageous in advanced integrated circuit (IC) fabrication for vertically etching high aspect ratio trenches and holes with nanometer scale features using, for example, anisotropic reactive ion etching (RIE), where a collimated ion flux of high energy ions is directed to the surface.

Anisotropic RIE is an ion-assisted chemical process, where energetic ions may sputter substrate material by breaking chemical bonds in a surface region to enhance chemical reactions with etchants diffusing to the surface. The directionality of the ion flux gives the etch process its anisotropy. The chemical reactions not only produce volatile byproducts that are removed but also produce solid byproducts that may deposit on an exposed surface forming a passivating layer that blocks the etchants. However, the passivation cannot occur if the passivating material is sputtered off by ions striking the surface. Thus, a vertically directed ion flux of high energy ions results in a vertically progressing etch front with a horizontal bottom surface being etched while vertical sidewalls get passivated. Additionally, a high vertical component of velocity of the high energy ions improves a directionality of the ion flux, which reduces ion loss to sidewalls of openings. This helps in supplying a sufficient number of energetic ions at the bottom of the openings during a high aspect ratio contact (HARC) etch process.

Controlling the ion energy of the high energy ions within a narrow range is desirable. The lower energy ions in the ion distribution spend a longer time in transit in the openings, which increases a chance of being scattered by randomizing collisions, resulting in more isotropic etching that may lead to bowing of sidewalls. The higher energy ions may deteriorate selectivity of the etch process to a masking layer or an etch stop layer. A commonly used dual signal approach is taken to help independently control various plasma properties. In this approach, a source signal may control, for example, an ionization rate while a bias signal controls the ion energy. In the embodiments in this disclosure, the narrow energy spread in the IEDF is achieved by applying a bias signal having an optimized waveform comprising triangle-shaped voltage spikes and a DC base voltage between the voltage spikes, referred to as a spike waveform. The energy spread in the IEDF of the high energy ions achieved with the bias signal having the spike waveforms is narrower compared to the energy spread obtainable by a rectangular pulsed waveform.

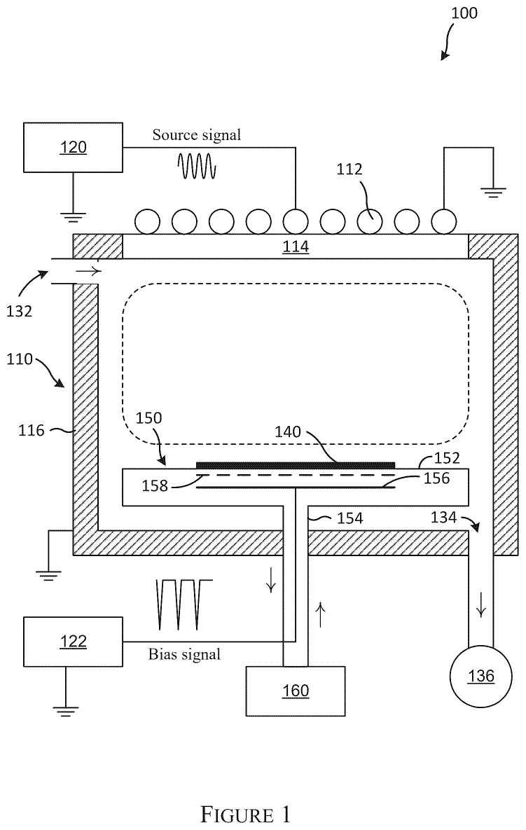

Generally, plasma for plasma processing is generated using electromagnetic (EM) power (e.g., an EM signal at a radio frequency (RF)) to ionize a gas flowing through a plasma processing chamber at a low pressure over a substrate to be processed. FIG. 1 illustrates a schematic of a plasma apparatus 100, including a cross-sectional view of a plasma processing chamber 110 suitable for performing an anisotropic RIE to form high aspect ratio features using embodiments of the method mentioned above.

In the example plasma apparatus 100 illustrated in FIG. 1, the plasma processing chamber 110 is configured in an inductively coupled plasma (ICP) mode, where a first electrode 112 disposed outside the plasma processing chamber 110 is configured to induce EM fields in the plasma within the plasma processing chamber 110. The induced EM fields couple RF power to the plasma to sustain the plasma by ionizing a discharge gas flowing through the plasma processing chamber 110. In this example, the first electrode 112 is a planar coil shaped RF antenna disposed over a ceiling of the plasma processing chamber 110. Since RF EM fields are shielded by metal, the ceiling has a dielectric window 114 made of a suitably hard material such as quartz or alumina. The RF power may be provided by coupling the source signal output from a first electrical circuit 120 to the first electrode 112. In some embodiments, in the ICP mode, the source signal may be applied at one end of the planar coil of the first electrode 112 located near the center of the dielectric window 114. The other end of the coil (near the edge of the dielectric window 114) may be connected to a reference potential of the plasma apparatus 100, referred to as ground. A ground connection is also made to a portion of a wall 116 of the plasma processing chamber 110, as illustrated in FIG. 1. The portion of the wall 116 to which the ground connection may be made is a conductive portion comprising, for example, a metal such as aluminum or stainless steel. A surface of the wall 116 facing the plasma may be coated with a hard ceramic insulator (e.g., yttria or alumina) to prevent sputtering and secondary electron emission off the wall 116.

In some embodiments, the source signal may be a continuous wave (CW) RF signal having an amplitude and an RF frequency generated from the first electrical circuit 120 comprising an RF oscillator, a power amplifier, and an impedance matcher between the power amplifier and the first RF electrode 106 for efficient power transfer. The first electrical circuit 120 may further include a chopper circuit configured to chop the CW RF waveform into a train of RF pulses, where each RF pulse has an RF waveform for a pulse duration. In some embodiments, the source signal is a waveform comprising such a train of temporally separated RF pulses, referred to as a pulsed RF waveform.

In the example embodiment illustrated in FIG. 1, the ICP mode is used to couple RF power to ionize a discharge gas flowing through the plasma processing chamber 110. However, other embodiments may use some other configuration to couple RF power to the plasma in the plasma processing chamber 110. For example, the plasma processing chamber 110 may be configured in a frequency resonance plasma (FREP) mode or a capacitively coupled plasma (CCP) mode. In the FREP mode, the first electrode 112 may be a planar coil, similar to the ICP mode, but its connections to the source signal may be at locations designed for RF resonance at the RF frequency of the source signal. In the CCP mode, the first electrode 112 is disposed inside the plasma processing chamber 110 in direct contact with the plasma. For example, the first electrode 112 may be a disc-shaped conductor in a top portion of the plasma processing chamber 110.

A controlled flow of the discharge gas flowing through the plasma processing chamber 110 may be maintained by a gas flow system coupled to the plasma processing chamber 110, as illustrated in FIG. 1. The gas flow system supplies a gaseous mixture comprising reactants, diluents, and additives to the plasma processing chamber 110 at controlled flow rates through a gas inlet 132. A gas outlet 134 is coupled to a vacuum pump 136 of the gas flow system to remove gas and maintain a controlled low pressure inside the plasma processing chamber 110. The gas pumped out through the gas outlet 134 may include volatile byproducts produced in the plasma processing chamber 110 during processing. Although the schematic in FIG. 1 shows a single gas inlet 132, gas outlet 134, and vacuum pump 136, multiple gas inputs, gas outlets, and vacuum pumps may be used to control the flow of gas inside the plasma processing chamber 110. Additionally, the gas flow system may include gas canisters, flow lines, gas flow sensors and controllers, throttle valves, and the like.

The plasma consists of mobile particles including positively charged ions, negatively charged electrons, and neutral radicals. The EM excitation and inter-particle collisions result in non-equilibrium velocity distributions of ions and electrons.

Bulk of the plasma has an almost equal density of mobile positive and negative charge, forming a charge-neutral core region (indicated by a dashed rectangle in FIG. 1), referred to as bulk plasma. Here both net charge density and electric field are negligible. However, a narrow high-field positive space charge region, referred to as plasma sheath, forms in a volume between the bulk plasma and a boundary surface confining the plasma. In bulk plasma, in the absence of a directed electric field and with ions being scattered in all directions by collisions with neutral particles, an ion drift velocity (defined as the mean velocity of the ion velocity distribution), is close to zero, implying that average kinetic energy of ions in the bulk plasma is dominated by its isotropic random component. In general, for a non-equilibrium velocity distribution, the average kinetic energy is a sum of its isotropic random component and its directed component. The random component is represented by an equivalent temperature (Tₑ for electron temperature and Tᵢ for ion temperature) and the directed component is represented by the drift velocity. As explained in detail below, the directed kinetic energy of the ion flux is acquired from the sheath electric field as the ions transit through the positive space charge region before striking the boundary surface.

The plasma sheath is formed by an initial transient of a high flux of net negative charge diffusing out of the plasma. The transient out-diffusion of negative charge results from light mass electrons having several orders of magnitude higher mobility than the much heavier ions. The differential transient fluxes of electrons and ions build up a net positive charged region in the vicinity of the boundary surface, creating an electric field that retards electrons and accelerates ions. As the space charge builds up, it rapidly establishes a steady state stable sheath between the charge-neutral bulk plasma and the boundary surface. As known to persons skilled in the art, a criterion for a stable sheath is that, everywhere in the sheath, the ion drift velocity exceeds a value, known as the Bohm velocity or the ambipolar speed of sound. So, to establish the stable sheath, a quasi-neutral pre-sheath region forms, where a relatively low electric field and voltage drop is supported by positive space charge encroaching into the otherwise charge-neutral bulk plasma. Ions diffusing out from the bulk plasma get accelerated by the electric field in the pre-sheath, resulting in the ion drift velocity increasing from about zero in the bulk plasma to the Bohm velocity at a sheath edge closer to the bulk plasma, the sheath edge on the opposite side being the boundary surface of the plasma. The Bohm velocity is roughly (Tₑ/M)^{1/2}, where M is the ion mass. Thus, by the time the ions enter the sheath, the directed component of the average kinetic energy has already exceeded the random component. The ions get further accelerated inside the sheath to very high velocities with which they strike the boundary surface.

Upon entering the sheath, the ions are swept to the boundary surface by a rapidly increasing electric field, often without suffering randomizing collisions with neutrals. With ions accelerating along a direction parallel to the field, the ion drift velocity profile in the sheath shows a rapid increase with reducing distance from the boundary surface of the plasma. This increase of the directed kinetic energy of ions accounts for most of the directed component of the average kinetic energy with which the ions strike the boundary surface. In the absence of randomizing collisions in the sheath, which is a good approximation considering the low pressure in the plasma processing chamber, the entire change in potential energy of the ions (determined by the voltage drop across the sheath) is converted to kinetic energy directed parallel to the electric field (i.e., normal to the boundary surface). During direct plasma processing, a top surface of the substrate is exposed to plasma, i.e., the boundary surface of the plasma includes the top surface of the substrate. Hence the top surface of the substrate is in contact with the sheath edge further away from the bulk plasma. Accordingly, the average directed kinetic energy of ions in the ion flux incident on the substrate is determined by the voltage drop across the plasma sheath directly above the major surface of the substrate, referred to as the sheath voltage. The sheath voltage is supported by a net positive space charge, referred to as the sheath charge.

As described above, the electric potential profile in the positive space charged plasma sheath is a potential barrier for negative charges (repels electrons) and a potential well for positive charges (attracts ions) entering the sheath from the bulk plasma. This gives a diode-like nature of the sheath that results in the voltage drop across the sheath having a self-bias even in a plasma processing apparatus using a single excitation source, where the excitation signal is a single frequency AC RF signal. But, it is difficult for a plasma apparatus with a single excitation source to control multiple plasma properties such as plasma density, ion energy, ion flux, radical flux, etc. Thus, two independent signal sources are often used to sustain plasma with two signals, viz., the source signal having a source signal waveform and the bias signal having a bias signal waveform.

The sheath voltage, hence the ion energy, is controlled primarily by the bias signal, and properties of the bulk plasma such as ionization rate, plasma density, and electron temperature are controlled primarily by the source signal. For this, the bias signal waveform is selected to be an asymmetric waveform having a high negative voltage portion to generate a large self-bias that accelerates positively charged ions to high kinetic energies. On the other hand, a symmetric source signal waveform, for example, a high frequency RF sinusoid may be selected to provide sufficient power to sustain the plasma without altering the self-bias significantly. In the absence of any bias signal, the self-bias, i.e., the sheath voltage is relatively small. Although there may be some coupling between the effects of the source and bias signals, the dual signal approach helps to decouple ion generation in the bulk plasma from ion acceleration in the plasma sheath in contact with the substrate.

The example plasma apparatus 100 is configured to couple EM power from two independent signal sources to sustain the plasma in the plasma processing chamber 110. In the plasma apparatus 100, the signal source for the source signal is the first electrical circuit 120 (described above), and a second electrical circuit 122 generates the bias signal.

Still referring to FIG. 1, a substrate 140 (which is the substrate to be processed, e.g., a semiconductor wafer in an intermediate stage of IC fabrication) is shown being held in a lower portion of the plasma processing chamber 110 over a multipurpose pedestal 150 of the plasma apparatus 100. The pedestal 150 comprises a platen 152 and a hollow stem 154 that connects to the platen 152 and extends outside the plasma processing chamber 110 through a floor of the plasma processing chamber 110. The pedestal 150 serves several functions utilizing various components placed in the platen 152, which may be controlled by equipment outside the plasma processing chamber 110 via the hollow stem 154.

In some embodiments, such as the example plasma apparatus 100 illustrated in FIG. 1, a second electrode 156 is placed in an insulating layer in an upper portion of the platen 152. For example, in some embodiment, the second electrode 156 may be a disc-shaped solid conductor embedded in a ceramic layer. In some other embodiments, the second electrode 156 may be a conductive mesh. The second electrode 156 in FIG. 1 is configured to be coupled to the bias signal output from the second electrical circuit 122 using an electrical connection through the hollow stem 154. As illustrated in FIG. 1, the substrate 140 is positioned vertically above the second electrode 156 with its backside in contact with a top surface of the platen 152. The top side of the substrate 140 (opposite the backside) is in contact with the plasma sheath for direct plasma processing. As mentioned above, the bias signal coupled to the second electrode 156 may control the sheath voltage of the plasma sheath in contact with the substrate 140, thereby control the kinetic energy of ions in the ion flux to the substrate 140. The bias signal waveforms used in the embodiments described in this disclosure are the spike waveforms that comprise triangle-shaped voltage spikes with rise times and fall times optimized to obtain a narrow energy spread of a high energy mode of the IEDF, narrower than that obtainable using a bias signal having a rectangular pulse waveform, as explained further below.

As described above, the second electrode 156 in the upper portion of the platen 152 is insulated from the substrate 140. However, the bias signal may be capacitively coupled to the plasma sheath by a capacitance of the region between the second electrode 156 and the sheath edge in contact with the top surface of the substrate 140, referred to here as platen capacitance. This region includes the substrate 140, but the platen capacitance is often designed to have a fixed value that is dominated by a capacitance of the insulating layer between the second electrode 156 and the backside the substrate 140, which is in contact with the top surface of the platen 152. This fixed capacitance value is roughly directly proportional to a ratio of a dielectric constant of the insulator to a distance between the second electrode 156 and the substrate 140.

In series with the platen capacitance is a sheath capacitance defined as a ratio of a change in the sheath charge to a change in the sheath voltage. Increasing the sheath voltage (e.g., by applying a negative bias voltage to the second electrode 156) not only increases the sheath charge but also makes the space charge region wider. This widening of the sheath lowers its capacitance. That is to say that the sheath capacitance is a voltage-dependent capacitance, which gets smaller when a negative voltage applied at the second electrode 156 pulls the substrate 140 to a more negative potential. Since the region between the second electrode 156 and the bulk plasma may be modeled as two capacitances in series (viz., the platen capacitance and the sheath capacitance), a step change in the bias voltage applied at the second electrode 156 gets split into a fraction dropped across the platen capacitance and a remaining fraction across the sheath capacitance. The lower the fraction dropped across the platen capacitance, the higher is the coupling to the substrate 140. Thus, the reduced sheath capacitance (reduced by the increased sheath voltage) helps couple the applied negative voltage from the second electrode 156 to the substrate 140. The coupling may be further assisted by selecting a high dielectric constant insulator for the platen and by placing the second electrode 156 close to the backside of the substrate 140 to achieve a high ratio of platen capacitance to sheath capacitance. Since a voltage change at the substrate 140 changes the sheath voltage by almost an equal amount, improving the coupling between the second electrode 156 and the substrate 140 enables the bias signal waveform applied to the second electrode 156 to control the sheath voltage more effectively.

Considering the high negative voltages typically used in bias signal waveforms, the isotropic random component of kinetic energy of ions in the ion flux incident on the substrate 140 is much smaller than the kinetic energy directed vertically by the sheath electric field, and, as explained above, due to a lack of collisions during transit through the sheath, the kinetic energy with which an ion strikes the substrate 140 is roughly equal to a drop in its potential energy in the sheath, as dictated by the voltage drop across the sheath. Ideally, a constant sheath voltage would yield an extremely narrow IEDF. However, because of RF oscillations and transient charging effects (described in further detail below) it may not be possible to achieve a constant potential at the surface of the substrate 140 by simply applying a DC bias signal at the second electrode 156. In general, the sheath voltage is a function of time, which results in an ion energy mode of the IEDF that has a modal ion energy and an energy spread that depends on the sheath voltage waveform that results from the applied bias signal. The effects of various bias signal waveforms on the IEDF, as well as various examples of synchronization of the bias signal with the source signal are described further below.

As mentioned above, the bias signals in the embodiments in this disclosure have spike waveforms comprising bias pulses, where each bias pulse is a triangle-shaped negative voltage spike for a spike duration followed by a DC base voltage for a base duration. As described further below, various parameters of the bias pulse shape may be adjusted to control the modal energy and the energy spread of the high energy mode, as well as the ion flux of the high energy ions striking the substrate 140.

In the example embodiment of the plasma apparatus 100, the pedestal 150 is utilized to first couple the spike waveforms of the bias signal from the second electrical circuit 122 to the second electrode 156 and then from the second electrode 156 to the substrate 140 to control the sheath voltage of the plasma sheath in contact with the substrate 140. However, as mentioned above, the pedestal 150 has multiple functions.

The upper portion of the platen 152 may also function as an electrostatic chuck (ESC). As illustrated in FIG. 1, in addition to the second electrode 156, gripping electrodes 158 of the ESC may be embedded in the insulating layer in the upper portion of the platen 152 closer to the top surface of the platen 152. Gripping electrodes 158 are typically placed within a few millimeters below the top surface of the platen 152, which is in contact with the backside of the substrate 140. In some embodiments, the insulating layer may include a semi-insulating material coated with an insulator. The gripping electrodes 158 may be a segmented conductive mesh configured to hold the substrate 140 electrostatically when biased by waveforms generated from DC power supplies outside the plasma processing chamber 110. The DC power supplies may be coupled to the gripping electrodes 158 using, for example, wires passing through the hollow stem 154.

The pedestal 150 in FIG. 1, may further house components of a thermal system 160 configured to maintain the substrate 140 at a desired temperature. The platen 152 may be fitted with liquid coolant pipes and electrical heater elements of the thermal system 160 to cool or heat the backside of the substrate 140. These components may be coupled to pumps and power supplies of the thermal system 160 through the stem 154 of the pedestal 150. The stem 154 may be further used by the thermal system 160 to pass a gas flow line to flow a cooling gas through grooves in the top surface of the platen 152 along the backside of the substrate 140. A controller of the plasma apparatus 100 may control the thermal system 160 to operate the various components to maintain the substrate 140 at the desired temperature using feedback from temperature sensors placed, for example, in the platen 152 to sense a temperature of the substrate 140.

The embodiments in this disclosure, adopts the commonly used dual signal approach to control various plasma properties. As described above with reference to FIG. 1, the source signal coupled from the first electrical circuit 120 to the first electrode 112 may be used to control bulk plasma properties such as ionization rate, plasma density, and electron temperature, and the bias signal coupled from the second electrical circuit 122 to the second electrode 156 may be used to control the ion energy. As explained above, the dual signal approach provides a better control of plasma properties by decoupling the control of ion generation in the bulk plasma from the control of ion acceleration in the plasma sheath by selecting the source signal to be symmetric around zero volts while selecting the bias signal to have a high negative voltage bias. In various embodiments of methods suitable for HARC etching using anisotropic RIE, bias signals having spike waveforms may be selected along with CW RF or pulsed RF source signals waveforms.

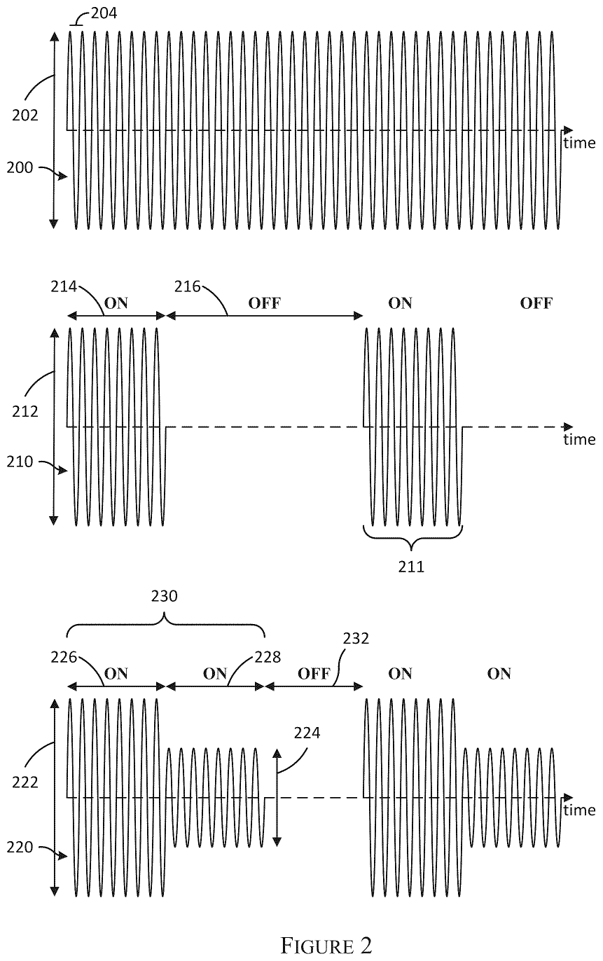

FIG. 2 illustrates plots of several example waveforms that may be used as the source signal in some embodiments in this disclosure. High frequency RF signals in a frequency range of about 10 MHz to about 2.45 GHz are commonly used as source signals. The source signal may have a continuous waveform or a pulsed waveform comprising a plurality of source pulses. Examples of both continuous and pulsed waveforms are illustrated in FIG. 2.

The source signal 200 is a CW RF waveform having an amplitude 202 and a period 204. As an example, amplitude may be measured by the peak to peak voltage. The frequency of the source signal 200 (defined as a reciprocal of the period 204) is an RF frequency. In FIG. 2, the CW RF waveform of the source signal 200 has been chopped to generate a periodic pulsed waveform of the source signal 210 comprising a plurality of temporally separated source pulses 211. The pulsed waveform in this example is the pulsed RF waveform (mentioned above), where each of the source pulses 211 is an RF pulse having an amplitude 212 and a pulse duration 214. There are no source pulses during a pulse separation time 216 between two consecutive source pulses 211. Clearly, one period of the periodic pulsed RF waveform of the source signal 210 is a sum of the pulse duration 214 and the pulse separation time 216. A reciprocal of the period is, by definition, the frequency of the periodic source signal 210. However, the RF waveform within the source pulses 211 has an RF frequency, not to be confused with the signal frequency.

In general, a signal comprising a plurality of temporally separated pulses has an ON state comprising the plurality of pulses and an OFF state with no pulses. Thus, the ON state of the source signal 210 comprises the plurality of source pulses 211 (i.e., the plurality of RF pulses), and the OFF state is the state of the source signal 210 during the pulse separation times 216. In contrast, the source signal 200 having the CW RF waveform has no OFF state; it is always in its ON state.

The source signal 220 is another example of a pulsed waveform comprising a plurality of source pulses 230. A difference between the source signal 220 and the source signal 210 is that, in the source signal 220, each of the source pulses 230 is a concatenation of a first source pulse having a first amplitude 222 and a second source pulse having a second amplitude 224 that is different from the first amplitude 222. Accordingly, the plurality of source pulses 230 is a combination of a first plurality of source pulses having the first amplitude 222 and a second plurality of source pulses having the second amplitude 224. The pulsed waveform in this example is referred to as a dual amplitude pulsed RF waveform. As illustrated in FIG. 2, the first source pulse has a first duration 226 and the second source pulse has a second duration 228. Thus, a pulse duration of each of the source pulses 230 is a sum of the first duration 226 and the second duration 228, and two consecutive source pulses 230 are temporally separated by a pulse separation time 232. Accordingly, the ON state of the source signal 220 comprises the combined first plurality of source pulses and second plurality of source pulses. The OFF state of the source signal 220 is the state with no pulses during the pulse separation times 232. One period of the dual amplitude pulsed RF waveform of the source signal 210 is a sum of the first duration 226, the second duration 228, and the pulse separation time 232. A reciprocal of the period is the frequency of the source signal 220. In this example, the first source pulses and the second source pulses have the same RF frequency. Thus, there is a single RF frequency for the source pulses 230.

The example source signals illustrated in FIG. 2 are sinusoidal waveforms. However, it is understood that other wave shapes, for example, a symmetric bipolar sawtooth or triangular wave shape may also be used.

It is noted that, in some embodiments, a signal comprising a plurality of pulses may have no OFF state, similar to the CW RF source signal 200, if the plurality of pulses forms a continuous train of pulses. For example, reducing the separation time 232 in the source signal 220 to zero creates a source signal comprising a continuous train of source pulses 230 with no OFF state, since there is no time duration with no source pulses.

As explained above with reference to FIG. 1, the bias signal generated by the second electrical circuit 122 and coupled to the second electrode 156 may control the sheath voltage of the plasma sheath in contact with the substrate 140, thereby control the kinetic energy of ions in the ion flux to the substrate 140. As explained above, in order achieve a high directionality for supplying energetic ions at the bottom of a high aspect ratio feature, it is desirable for the IEDF to have a mode at a high modal energy with a narrow energy spread. Unfortunately, the commonly used bias signal waveforms, viz., a negatively biased low frequency RF waveform and a low frequency pulsed DC bias waveform comprising a plurality of rectangular pulses result in excessive broadening of the high energy mode of the IEDF. However, as known to persons skilled in the art, a complex tailored trapezoidal pulse shape may be used to overcome broadening of the IEDF associated with the commonly used bias signal waveforms mentioned above. But, implementing bias signals having pulses with the tailored trapezoidal pulse shape may be costly. The manufacturing cost may be increased because expensive custom waveform generation hardware may have to be used to synthesize the complex tailored pulse shape. In contrast, it is relatively simple to implement bias signals having spike waveforms comprising triangular voltage spikes, along with the continuous or pulsed RF source signal waveforms (see FIG. 2). Both the bias and the source signal waveform used in the embodiments described in this disclosure may be generated with relatively inexpensive standard hardware. The impact of the various bias signal waveforms on the energy spread of the high energy mode in the IEDF of the ion flux incident on the substrate 140 is described below.

The commonly used negatively biased low frequency RF bias waveform is, typically an asymmetric sinusoid having a frequency of about 100 kHz to about 13.56 MHz. The asymmetry is obtained by superposing a negative DC bias on a symmetric sinusoid. Typically, the negative DC bias and an amplitude of the sinusoid are selected such that the negatively biased low frequency RF bias waveform oscillates between a large negative voltage and a small positive voltage. The second electrode 156 being capacitively coupled to the sheath by the platen capacitance (as explained above), the oscillating voltage at the second electrode 156 results in an RF modulated time-varying potential at the top surface of the substrate 140. For plasmas used in plasma processing for IC fabrication, the bulk plasma has an approximately constant DC potential (e.g., about 10 V to about 50 V above ground). Hence, the time-varying potential at the top surface of the substrate 140 implies a time-varying sheath voltage.

The negative voltage swing generates a respective sheath voltage that accelerates ions, thus creating the desired high energy mode in the IEDF. However, there is a spread in the ion energy that is reflective of the temporal variations of the sheath voltage. As explained above, the kinetic energy acquired by each ion is roughly equal to its loss in potential energy in the sheath. In other words, the kinetic energy with which the ion exits the sheath and strikes the substrate 140 is dictated by the voltage drop it experiences during transit through the sheath. Because the sheath voltage here is a time-varying voltage, this voltage drop is not constant; it depends on the phase of the low frequency RF bias waveform at the time the ion enters the sheath. Hence, the ion flux comprises ions with varying kinetic energies, resulting in an undesirable broadening of the high energy peak in the IEDF.

The voltage swing in the opposite direction, where the bias signal is rising from the large negative voltage up to a slightly positive voltage, helps discharge positive charges that may accumulate on the substrate 140 because of excess ion current during the negative swing.

The energy spread of the high energy ions may even be bi-modal and include a secondary mode in addition to the primary mode. The secondary mode may be due to the portion of the bias signal waveform having voltages close to and above zero volts and include fewer ions at a lower modal energy relative to the primary mode.

As explained above, a constant sheath voltage would yield an extremely narrow IEDF. Thus, variations of the potential at the top surface of the substrate 140 with time translates to a variable sheath voltage that generates ions with various energies in the ion flux to the substrate 140. Thus, reducing voltage variations at the surface in contact with the plasma sheath may reduce the energy spread in the IEDF of the ion flux striking the surface. But, it is difficult to maintain a nearly constant negative bias at a surface that is receiving a net flux of positive charge from the bulk plasma. Consider a negative step voltage being applied at the second electrode 156. Initially, the applied negative voltage step splits between a voltage drop across the platen capacitance and a voltage drop across the sheath capacitance in series with the platen capacitance, in a ratio of a reciprocal of the platen capacitance to that of the sheath capacitance. (Indeed, as described above, the capacitance values are typically designed to have most of the applied negative voltage dropping across the sheath capacitance.) However, the negative voltage step at the boundary surface between the sheath and the substrate 140 initiates an excess ion flux (in excess of the electron flux) to the substrate 140 that constitutes an ion current that continuously raises the potential at the surface between the sheath and the substrate 140 till the entire applied negative voltage drops across the platen capacitance, thereby eliminating the high energy mode in the IEDF.

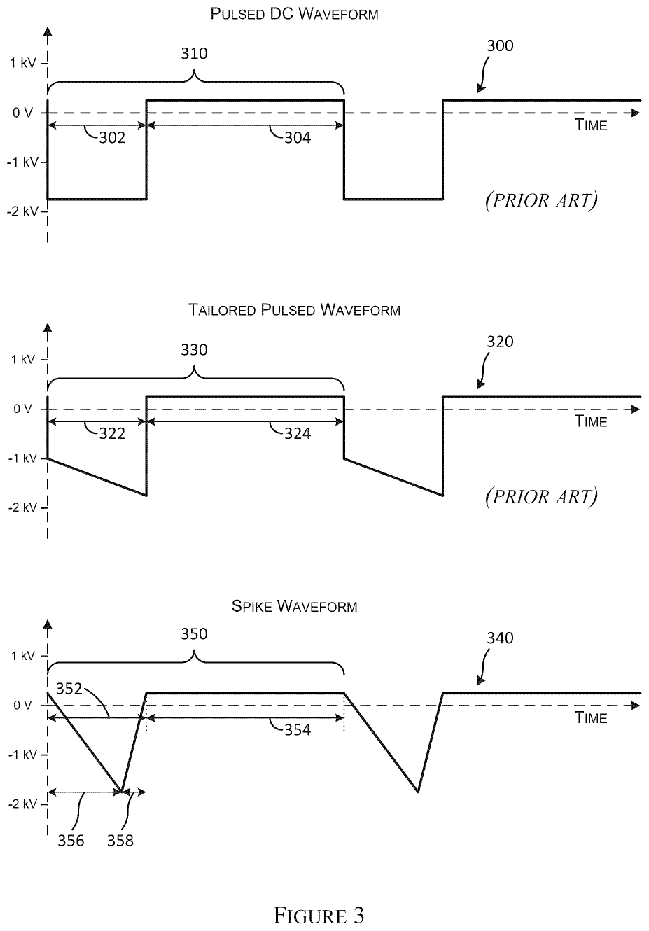

The charging of the platen capacitance by the ion current to the substrate 140 (described above) may be countered by periodically discharging the platen capacitance and resetting the potential at the top surface of the substrate 140. This may be achieved by using, for example, a bias signal 300 having a pulsed DC waveform comprising a plurality of rectangular bias pulses 310, as illustrated in FIG. 3. Each of the rectangular bias pulses 310 comprises two cycles, a negative voltage cycle 302 and a positive voltage cycle 304, as illustrated in FIG. 3.

The negative voltage cycle 302 is a rectangular negative voltage pulse having a rising edge, where the bias signal 300 makes an almost discontinuous jump from a positive base voltage to a relatively high negative peak voltage. The bias signal 300 is then maintained at a constant (or DC) value equal to the negative peak voltage for a pulse duration of the negative voltage cycle 302. When the bias signal 300 is applied at the second electrode 156, the sharp transition at the rising edge pulls the potential at the top surface of the substrate 140 to a high negative value that is typically designed to be close to the high negative peak voltage. This initiates accumulation of positive charge in the substrate 140 due to the ion current described above. Consequently, during the pulse duration, the cumulative positive charge transferred to the substrate 140 by the ion current charges the platen capacitance. Note that, throughout the pulse duration of the negative voltage cycle 302, the voltage at the second electrode 156 remains at a constant DC value equal to the negative peak voltage of the bias signal 300. Thus, during this time, the voltage at the sheath edge in contact with the substrate 140 keeps rising continuously from its high negative value toward zero volts, thereby reducing the sheath voltage available to accelerate ions to high kinetic energies. A consequence of maintaining a constant voltage at the second electrode 156 is that the ion current not only increases the voltage drop across the platen capacitance but also reduces the voltage drop across the sheath capacitance by an equal amount. This change in the sheath voltage (equal to the change in the voltage drop across the substrate 140 and the platen 152 between the substrate 140 and the second electrode 156) is given by the positive charge accumulated on the substrate 140 divided by a sum of the platen capacitance and the sheath capacitance. The continuously changing sheath voltage during the time when the bias signal 300 is constant at the negative peak voltage gives rise to ions with varying kinetic energies in the ion flux to the substrate 140, resulting in an undesirable broadening of the high energy peak in the IEDF.

The charge deposited by the ion current during the negative voltage cycle 302 may be discharged during the positive voltage cycle 304. The falling edge of the negative voltage pulse at the end of the negative voltage cycle 302 starts the positive voltage cycle 304 of the rectangular bias pulse 310. As illustrated in FIG. 3, the bias signal 300 makes another step change from the negative peak voltage to return to the positive base voltage, after which the bias signal 300 remains constant at the base voltage for a base duration. The sharp transition to the positive base voltage at the falling edge pulls the potential at the top surface of the substrate 140 higher, resulting in an increase in an electron current to the substrate 140. The negatively charged electrons neutralize the positive charge accumulated on the substrate 140. Neutralizing the positive charge discharges the platen capacitance, and the rising edge of the next rectangular bias pulse 310 returns the surface potential of the substrate voltage to its high negative value.

Generally, the pulsed DC waveforms of the bias signal 300 may provide better control of the IEDF relative to the low frequency RF waveforms. However, the changing sheath voltage during the negative voltage cycle 302 (described above) may broaden the energy spread of the IEDF excessively to be suitable for etching the increasingly high aspect ratio of the 3D structures used in advanced IC technologies.

The energy spread in the IEDF due to the continuously changing sheath voltage during the pulse duration of the rectangular negative voltage pulse in the pulsed DC waveform of the bias signal 300 is addressed in the bias signal 320, plotted in FIG. 3. The bias signal 320 has a tailored pulsed waveform comprising a plurality of trapezoidal bias pulses 330, where each of the trapezoidal bias pulses 330 may be obtained from the rectangular bias pulse 310 by replacing the rectangular negative voltage pulse in its negative voltage cycle 302 with a trapezoidal negative voltage pulse to obtain a negative voltage cycle 322 of the bias signal 320. The constant DC voltage of the rectangular voltage pulse is replaced, in the trapezoidal voltage pulse, by a linear ramp from a first negative voltage to a second negative voltage that is more negative, as illustrated in FIG. 3. At the rising edge of the trapezoidal negative voltage pulse of the negative voltage cycle 322, the bias signal 320 steps abruptly from a positive base voltage to the first negative voltage of its voltage ramp. The bias signal 320 is then ramped linearly to the second negative voltage of its voltage ramp during a pulse duration of its negative voltage cycle 322.

When the bias signal 320 is applied at the second electrode 156, the rising edge of the trapezoidal negative voltage pulse pulls the potential at the top surface of the substrate 140 to a high negative value close to the first negative voltage. As explained above, the negative voltage transition at the boundary surface between the sheath and the substrate 140 initiates accumulation of positive charge in the substrate 140 due to the excess ion current. The charge accumulating in the substrate increases the voltage drop across the platen capacitance. Note that, a change in the voltage drop across the platen capacitance has to be equal to a sum of any increase in the voltage at the top surface of the substrate 140 and any decrease in the voltage at the second electrode 156. As explained above, since the bias signal 300 has a rectangular negative voltage pulse, there is no decrease in the voltage at the second electrode 156. Hence, the voltage at the top surface of the substrate 140 has to increase to accommodate the higher voltage drop across the platen capacitance. In contrast, the bias signal 320, has a trapezoidal negative voltage pulse, for which the voltage at the second electrode 156 is decreasing. By changing the total voltage drop across the series combination of the platen capacitance and the sheath capacitance it is now possible to control the potential at the boundary surface between the substrate and the sheath. Thus, the increase in voltage at the top surface of the substrate 140 that occurs due to the ion current when the second electrode is held at a negative DC voltage may be compensated by decreasing the voltage at the second electrode 156 to accommodate the higher voltage drop across the platen capacitance instead of increasing the voltage at the top surface of the substrate 140 and reducing the sheath voltage. The voltage step of the rising edge and a slope of the ramp in the tailored pulsed waveform of the bias signal 320 may be adjusted to set the potential at the sheath edge in contact with the substrate 140 at a quasi-constant value, a technique often referred to as current compensation. Thus, as expected, the tailored pulsed waveform, such as the waveform of the bias signal 320, provides a narrower energy spread at the same modal energy of the IEDF relative to the pulsed DC waveform, such as the waveform of the bias signal 300.

As known to persons skilled in the art, generating a properly adjusted tailored pulsed waveform is expensive and requires custom pulse generation hardware. In contrast, a spike waveform such as the spike waveform of the bias signal 340, illustrated in FIG. 3, may be generated using relatively inexpensive standard hardware. The spike waveform comprises a plurality of bias pulses 350, where each of the bias pulses 350 has a voltage spike for a spike duration 352 and a DC base voltage for a base duration 354. A sum of the spike duration 352 and the base duration 354 is equal to a pulse period. In various embodiments, a pulse frequency (defined as a reciprocal of the pulse period) may be from about 100 kHz to about 1 MHz. As illustrated in FIG. 3, the voltage spike has a leading transition from the DC base voltage to a peak voltage during a rise time 356, followed by a trailing transition from the peak voltage to the DC base voltage during a fall time 358. The bias signal 340 changes continuously during the spike duration 352, so a sum of the rise time 356 and the fall time 358 is equal to the spike duration 352. The voltage spike in the example bias pulse 350 is a triangular pulse, but, it is understood that some other pulse shape having a continuous leading transition from the DC base voltage to the peak voltage followed by a trailing transition, where the voltage returns continuously to the DC base voltage, may be used.

The peak voltage has a high negative value such that, when the voltage spike of the bias pulse 350 is applied at the second electrode 156, the sheath voltage is set to a high enough value to accelerate ions to a high kinetic energy. The DC base voltage has a slightly positive value to ensure that the charge deposited by the ion current during the spike duration is neutralized and the positive sheath charge adjusted quickly to settle the sheath voltage from the high self-bias to a low self-bias that is set by the DC base voltage value. The reduction of the positive charges starts during the fall time and extends for a short time into the base duration.

A comparison of the tailored pulsed waveform of the bias signal 320 and the spike waveform of the bias signal 340, illustrated in FIG. 3, shows that the spike waveform incorporates features of the tailored pulse waveform with a simpler pulse shape to provide an added advantage of lower cost. The rise time 356 may be adjusted to co-optimize the leading transition to pull the top surface of the substrate 140 to a high negative value controlled by the peak voltage as well as provide the current compensation effect (described above) to effectively counter the ion current accumulating positive charge in the substrate 140 from raising the potential at the top surface of the substrate 140 during the leading transition. Accordingly, it is expected that the spike waveform, such as the waveform of the bias signal 340 would provide a narrower IEDF relative to the pulsed DC waveform, such as the waveform of the bias signal 300, similar to that provided by the tailored pulsed waveform, such as the waveform of the bias signal 320. In various embodiments, the rise time may be from about 100 nanoseconds to about 1 microsecond.

The fall time 358 may be adjusted to rapidly discharge the platen capacitance and return the sheath voltage smoothly to the low value controlled by the base voltage. In some embodiments, the fall time is selected to be short to remove excess sheath charge to minimize the number of ions that reach the substrate while the sheath voltage is being reduced to the low self-bias. In various embodiments, the rise time may be from about 100 nanoseconds to about 1 microsecond.

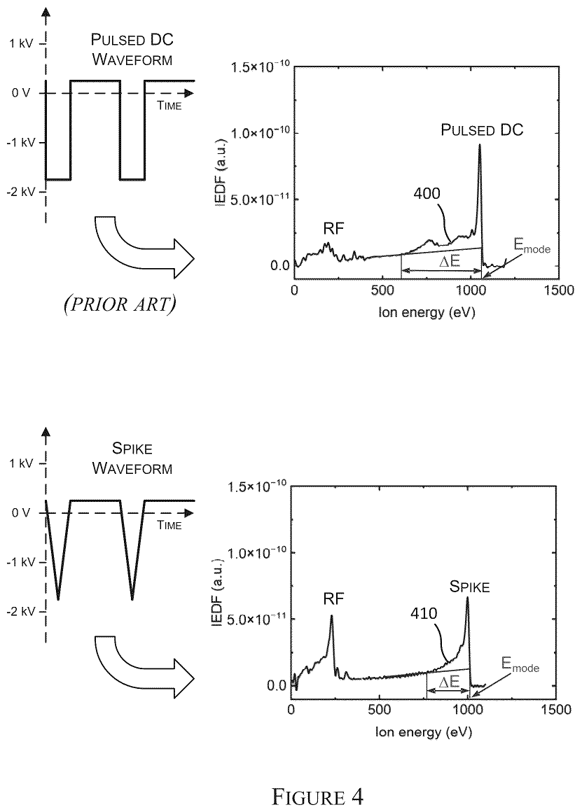

Results of controlled experiments performed by the inventors are plotted in FIGS. 4-6. It is noted that, although the example embodiment illustrated in FIG. 1 has used the plasma processing chamber 110 configured in the ICP mode, the experiments were performed using a plasma processing chamber configured in the CCP mode.

The experimental data plotted in FIG. 4 confirm that the IEDF of an ion flux obtained with a bias signal having a pulsed DC waveform has a wider energy spread of a mode at a high modal energy relative to the energy spread of a mode at the same modal energy in the IEDF of an ion flux obtained using a bias signal having a spike waveform. FIG. 4 compares the IEDF 400 of the ion flux obtained using a bias signal having a pulsed DC waveform with the IEDF 410 of the ion flux obtained with a bias signal having a spike waveform. In both cases, a high frequency (30 MHz) CW RF source signal has been used. As illustrated in FIG. 4, both the IEDF 400 (associated with the pulsed DC waveform) and the IEDF 410 (associated with the spike waveform) have a high energy mode at a modal energy (E_{mode}) of about 1000 eV.

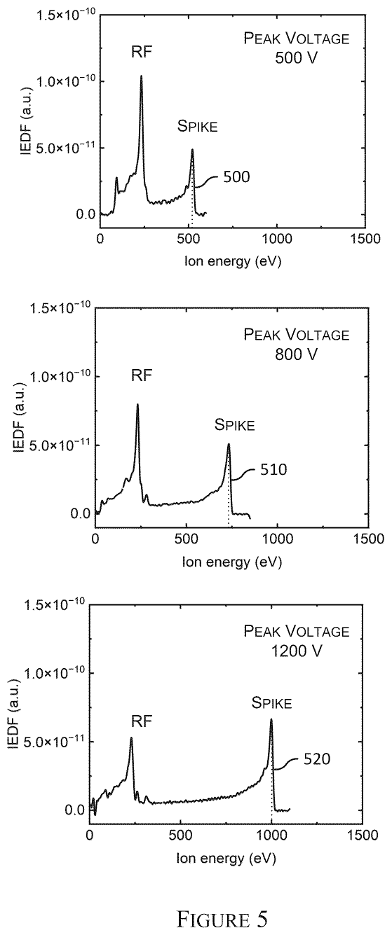

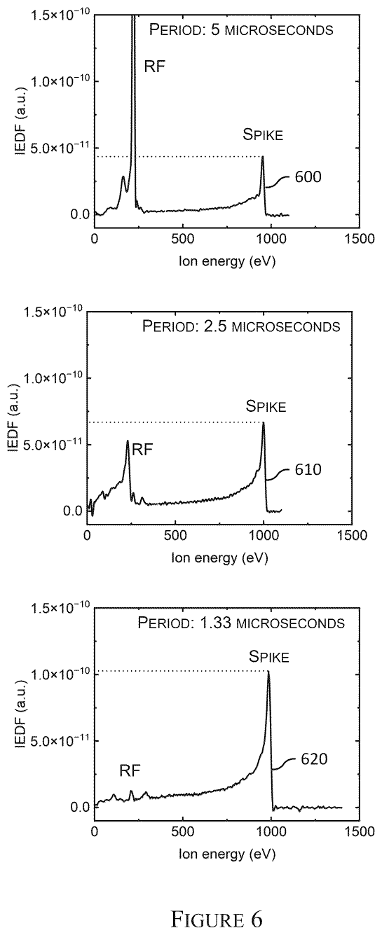

A low energy mode at a modal energy of about 200 eV is also present in both the IEDF 400 and the IEDF 410. This low energy mode, also seen for the IEDFs of the bias signals shown in FIG. 5 and FIG. 6, is discussed further below.

The IEDF 400 shows a broadening of its high energy mode, with an energy spread (ΔE), indicated by a double arrow in the plot of the IEDF 400 in FIG. 4. A respective energy spread (ΔE) of the high energy mode of the IEDF 410 is indicated by another double arrow in the plot of the IEDF 410 in FIG. 4. As expected, ΔE in the IEDF 400 of the ion flux obtained using the pulsed DC waveform is about 450 eV, which is much larger than the ΔE in the IEDF 410 of the ion flux obtained using the spike waveform, where ΔE is about 250 eV. This shows that the spread in energy of ions in the high energy mode has been reduced by using the spike waveform instead of the pulsed DC waveform.

The spike waveform allows the modal energy of the high energy mode of the IEDF and a magnitude of the ion flux to the substrate 140 to be changed independently. The modal energy of the high energy ions may be adjusted by changing the peak voltage of the voltage spikes of the spike waveform. The magnitude of the ion flux to the substrate 140 may be adjusted by changing the number of voltage spikes per unit time in the spike waveform without altering the voltage spike. This may be achieved by changing the pulse period by changing the base duration. Reducing the base duration reduces the pulse period, which increases the number of voltage spikes per unit time. By changing the base duration to change the pulse period independently from changing the peak voltage, the magnitude of the ion flux may be changed independently from changing the modal energy of the high energy ions in the ion flux.

FIG. 5 illustrates plots of IEDF displaying data of ion energy measured by the inventors from three ion fluxes obtained using three bias signals having spike waveforms with different values of the peak voltage to demonstrate the impact of changing the peak voltage on the modal energy of the high energy mode. In the three plots illustrated in FIG. 5, the values of the peak voltage are 500 volts, 800 volts, and 1200 volts, for the IEDF 500, IEDF 510, and IEDF 520, respectively. As illustrated in FIG. 5, the modal energy increased from about 500 eV to about 750 eV and from about 750 eV to about 1000 eV when the peak voltage was increased from 500 volts to 800 volts and from 800 volts to 1200 volts. This data indicates that the modal energy may be controlled by the peak voltage of the voltage spikes of the spike waveform.

FIG. 6 illustrates plots of IEDF displaying data of ion energy measured by the inventors from three ion fluxes obtained using three bias signals having spike waveforms with different values of the pulse period to demonstrate the impact of changing the pulse period on the ion flux to the substrate 140. As described above, the pulse period has been changed by changing the base duration time. In the three plots illustrated in FIG. 6, the values of the pulse period are 5 microseconds (200 kHz), 2.5 microseconds (400 kHz), and 1.33 microseconds (600 kHz), for the IEDF 600, IEDF 610, and IEDF 620, respectively. As illustrated in FIG. 6, the value of the IEDF at the modal energy (about 1000 eV) increased by about 1.7 times when the period was reduced from 5 microseconds to 2.5 microseconds and by another 1.5 times when the period was reduced from 2.5 microseconds to 1.33 microseconds. The IEDF at any energy being a measure of probability density of ions at that energy, the flux of high energy ions is expected to increase as the IEDF at the modal energy increases. Thus, this data indicates that the ion flux may be controlled by the pulse period of the bias pulses of the spike waveform, where the pulse period is changed by changing the base duration.

In all the IEDFs shown in FIGS. 4-6, a low energy mode is present in addition to the high energy mode discussed above. This low energy mode in the IEDF is due to the RF source signal, which is coupled to the plasma to supply the ions entering the sheath. As mentioned above, the presence of low energy ions increases the chance of undesirable bowing of sidewalls. However, the low energy ion fluxes generated by the RF source signal may be controlled with optimization of plasma parameters (e.g., RF source power and gas pressure in the plasma processing chamber) as well as parameters of the spike waveform (as is evident from the IEDFs in FIG. 5 and FIG. 6, discussed further below). The experiments that were performed to generate the IEDF data in FIGS. 4-6 have not been designed with optimized parameters. For example, the modal energy due to the RF source signal may be reduced from about 200 eV to less than 50 eV by changing the configuration of the plasma processing chamber from the CCP mode to the ICP mode. These experiments were designed to demonstrate that (i) the energy spread of the high energy mode may be improved by using spike waveforms instead of pulsed DC waveforms, and (ii) one can independently control a magnitude of the ion flux and the modal energy of the high energy mode by independently controlling the base duration and the peak voltage of the spike waveform.

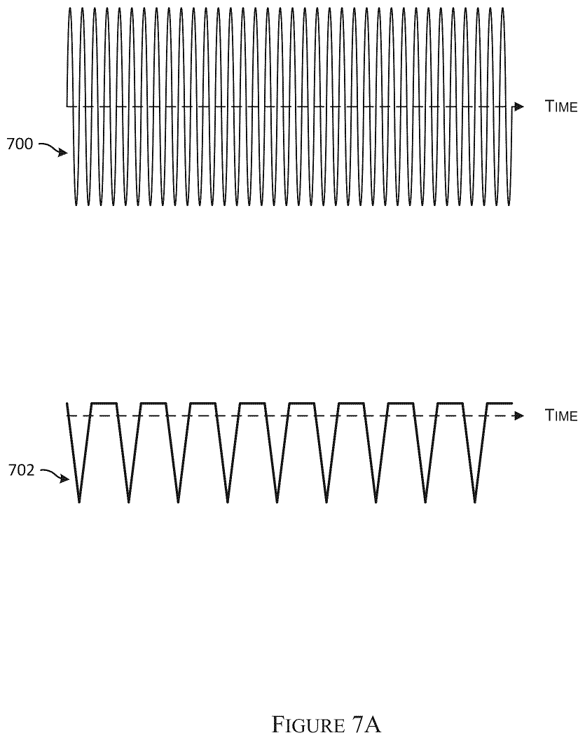

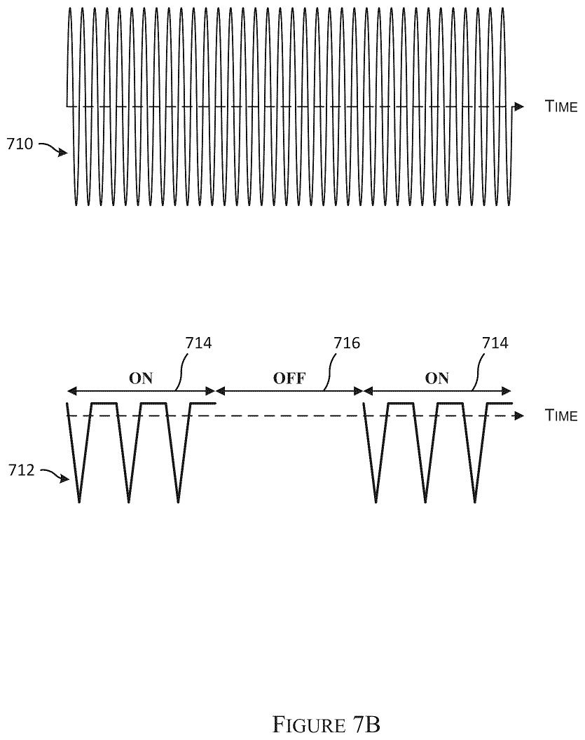

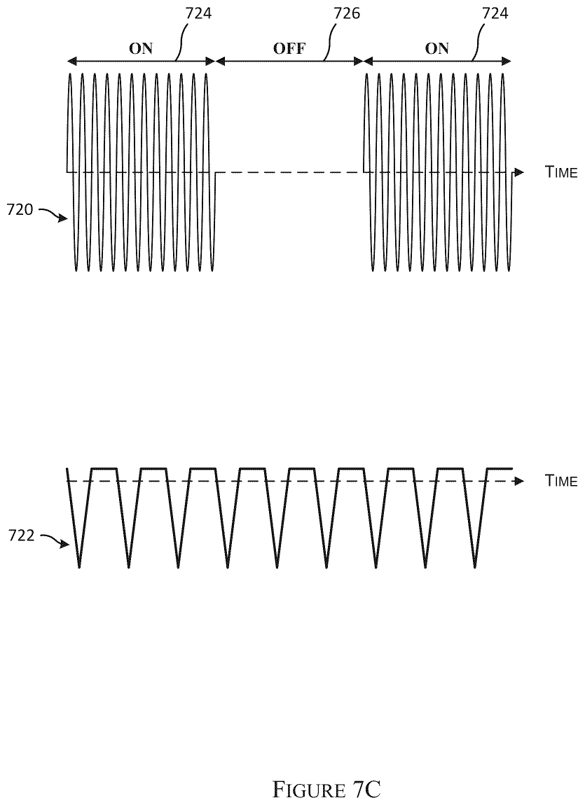

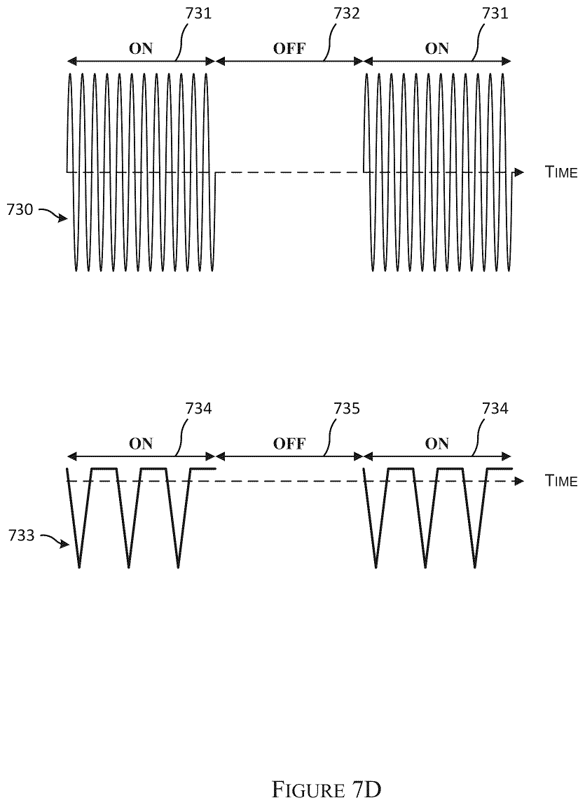

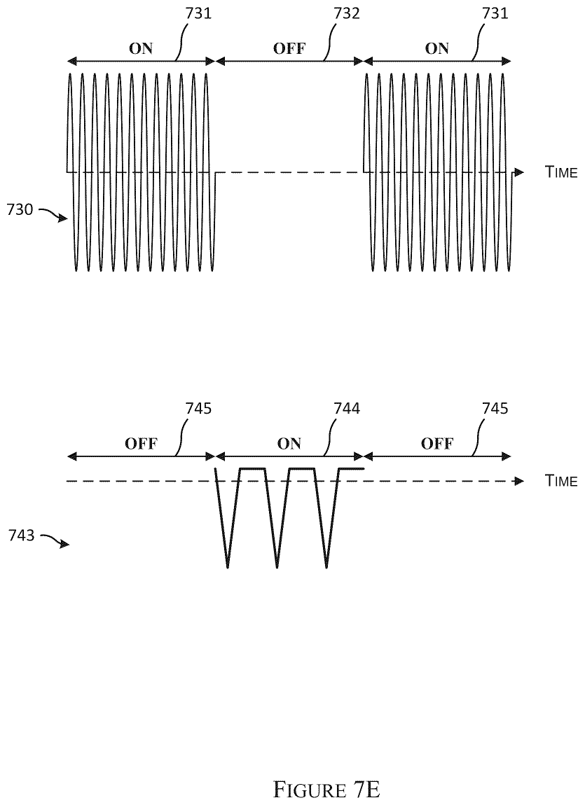

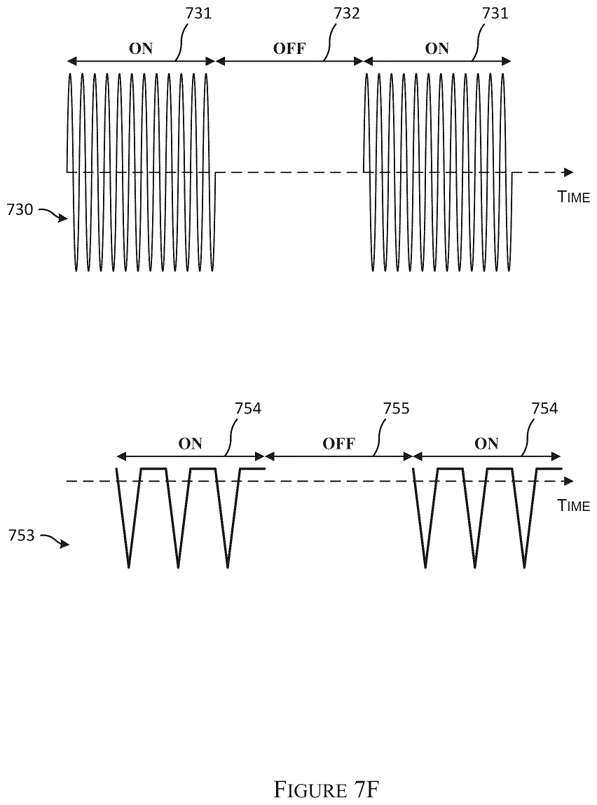

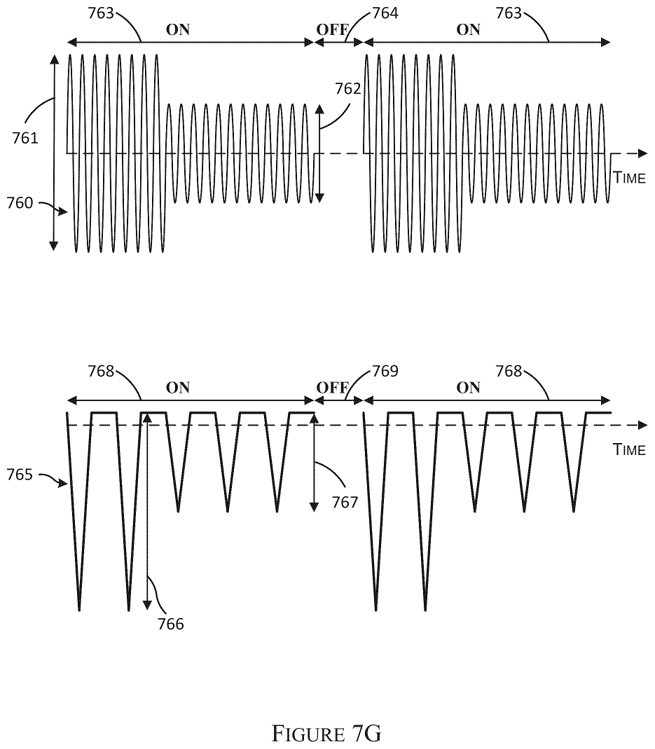

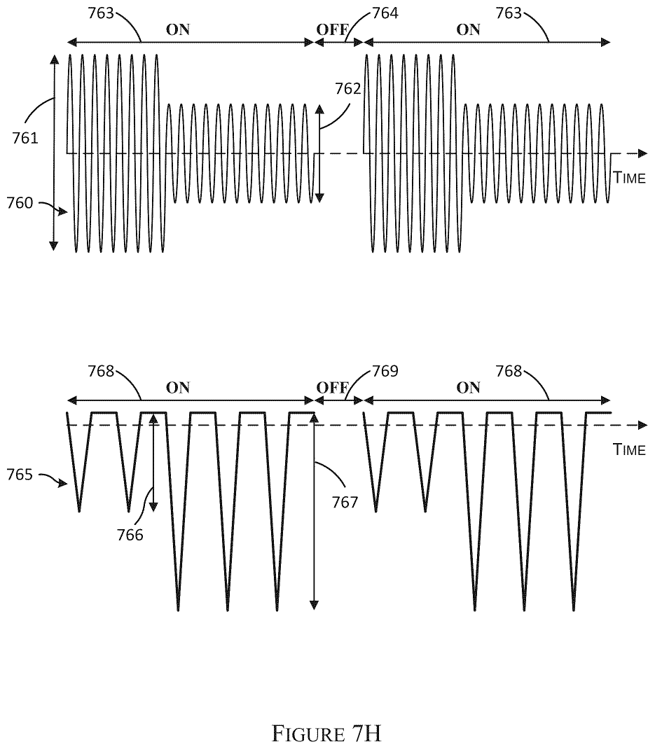

FIGS. 7A-7H illustrate plots of various pairs of a source signal and a bias signal waveform for various plasma processing applications. The source signal in the example embodiments in FIGS. 7A-7H has either the CW RF waveform, the pulsed RF waveform, or the dual amplitude pulsed RF waveform, described above with reference to FIG. 2. The bias signal in the example embodiments described with reference to FIGS. 7A-7H has a spike waveform.

Spike waveforms comprise a plurality of bias pulses, such as the bias pulse 350 of the bias signal 340, described above with reference to FIG. 3. The spike waveform of the bias signal 340 is a continuous train of bias pulses. As explained above, a continuous train of bias pulses has no OFF state, similar to the CW RF source signal 200. In addition to the plurality of bias pulses being a continuous train of bias pulses, the plurality of bias pulses of a spike waveform may be divided into a plurality of bursts, wherein each of the bursts is a concatenation of bias pulses. The spike waveform with bursts has an ON state comprising the bursts and an OFF state with no bursts. This is similar to the pulsed RF waveform 210 and the dual amplitude pulsed RF waveform 220 having an ON state comprising source pulses and an OFF state with no source pulses.

While the continuous signals are simpler, several applications of anisotropic plasma etching, including HARC etch processes, use source signals having the more complex pulsed RF or dual amplitude pulsed RF waveforms. Likewise, there are applications using bias signals having waveforms comprising bursts. These waveforms provide more flexibility in designing plasma processes where, for example, the plasma is turned off and ignited intermittently, or where a radical flux and an ion flux may be adjusted dynamically to vary a radical flux to ion flux ratio. Note that in embodiments, where the source signal and the bias signal are not continuous signals, the two signals may be synchronized in various ways depending on the application, as described below.

FIG. 7A illustrates plots of a source signal 700 having a CW RF waveform and a bias signal 702 having a spike waveform, where the plurality of bias pulses of the spike waveform is a continuous train of bias pulses.

FIG. 7B illustrates plots of a source signal 710 having a CW RF waveform and a bias signal 712 having a spike waveform, where the plurality of bias pulses of the spike waveform is divided into a plurality of bursts. For the sake of specificity, in this example embodiment, a duration of each burst is chosen to be equal to the separation between successive bursts. The bias signal has an ON state 714 and an OFF state 716.

FIG. 7C illustrates plots of a source signal 720 having a pulsed RF waveform, and a bias signal 722 having a spike waveform, where the plurality of bias pulses of the spike waveform is a continuous train of bias pulses. Again, for the sake of specificity, in this example embodiment, a duration of each RF pulse of the source signal 720 is chosen to be equal to the separation between successive RF pulses. The source signal 720 has an ON state 724 and an OFF state 726.

FIG. 7D illustrates plots of a source signal 730 having a pulsed RF waveform, and a bias signal 733 having a spike waveform, where the plurality of bias pulses of the spike waveform is divided into a plurality of bursts. As before, for the sake of specificity, in this example embodiment, a duration of each RF pulse of the source signal 730 is equal to the separation between successive RF pulses. The source signal 730 has an ON state 731 and an OFF state 732. In this example embodiment, a duration of each burst of the bias signal 733 is equal to the separation between successive bursts and is equal to the duration of each of the RF pulses of the source signal 730. However, this is not to be construed to be limiting. It is understood that unequal duration times may also be used. The bias signal 733 has an ON state 734 and an OFF state 735. Note that, in this embodiment, the ON state 731 of the source signal 730 is in phase with the ON state 734 of the bias signal 733, and the OFF state 732 of the source signal 730 is in phase with the OFF state 735 of the bias signal 733.

In the example embodiment in FIG. 7E the same source signal 730 (same as in the embodiment described with reference to FIG. 7D) has been used. However, a different bias signal 743 is used. The bias signal 743 may be obtained by a phase shift of the bias signal 733 (see FIG. 7D). The phase shift used to obtain the bias signal 743 is equivalent to a time delay equal to the duration of each bias pulse of the bias signal 733. The bias signal 743 has an ON state 744 and an OFF state 745. In this embodiment, the ON state 731 of the source signal 730 is out of phase with the ON state 744 of the bias signal 743, and the OFF state 732 of the source signal 730 is out of phase with the OFF state 745 of the bias signal 743.

In the example embodiment in FIG. 7F the same source signal 730 (used in the embodiments in FIG. 7D and FIG. 7E) has been used again. Also, similar to the embodiment in FIG. 7E, a bias signal 753 is obtained by a phase shift of the bias signal 733. However, the phase shift used to obtain the bias signal 753 is different from that used to obtain the bias signal 743. The bias signal 753 is obtained by a phase shift equivalent to a time delay that is less than the equivalent time delay used to obtain the bias signal 743. Consequently, the ON state 731 of the source signal 730 partially overlaps with the ON state 754 of the bias signal 753, and the OFF state 732 of the source signal 730 partially overlaps with the OFF state 755 of the bias signal 753.

FIG. 7G illustrates plots of a source signal 760 having a dual amplitude pulsed RF waveform comprising a plurality of source pulses with dual amplitudes, and a bias signal 765 having a spike waveform comprising a plurality of bias pulses with dual peak voltages, referred to here as a dual peak voltage spike waveform. The dual amplitude pulsed RF waveform has been described above with reference to the source signal 220 in FIG. 2. The dual amplitude pulsed RF waveform of the source signal 760 has a first plurality of first source pulses having a first amplitude 761 and a second plurality of second source pulses having a second amplitude 762. The plurality of source pulses of the dual amplitude RF waveform comprises the first plurality of first source pulses and the second plurality of second source pulses. As illustrated in FIG. 7G, the source signal 760 has an ON state 763 comprising the plurality of source pulses and an OFF state with no source pulses.

Similar to each of the source pulses of the dual amplitude pulsed RF waveform, each of the bias pulses of the dual peak voltage spike waveform of the bias signal 765 is a concatenation of a first bias pulse having a first peak voltage 766 and a second bias pulse having a second peak voltage 767 that is different from the first peak voltage 766. The dual peak voltage spike waveform of the bias signal 765 has a first plurality of first bias pulses having the first peak voltage 766 and a second plurality of second bias pulses having the second peak voltage 767. The plurality of bias pulses of the dual peak voltage bias waveform comprises the first plurality of first bias pulses and the second plurality of second bias pulses. In this example, the bias signal 765 is not a continuous train of bias pulses. Successive bias pulses are temporally separated by a separation time during which there are no bias pulses. Thus, the bias signal 765 has an ON state 768 comprising the plurality of bias pulses and an OFF state 769 with no bias pulses, as illustrated in FIG. 7G.

In the example embodiment illustrated in FIG. 7G the first plurality of first bias pulses is synchronized with the first plurality of first source pulses and the second plurality of second bias pulses is synchronized with the second plurality of second source pulses. In another example embodiment illustrated in FIG. 7H the second plurality of second bias pulses is synchronized with the first plurality of first source pulses and the first plurality of first bias pulses is synchronized with the second plurality of second source pulses.

Embodiments of a method for direct plasma processing of semiconductor substrates has been described above. The RF source signal waveforms and spike bias signal waveforms illustrated in FIG. 2, FIG. 3, and FIGS. 7A-7H are not an exhaustive set; various other waveforms may be derived by persons skilled in the art from the description of the plasma processing method and the example embodiments described above.

The plasma processing method comprises sustaining plasma in a plasma processing chamber by coupling a source signal providing EM power to ionize a gas flowing over the substrate being processed in the plasma processing chamber. Along with the source signal, a bias signal having a spike waveform comprising a plurality of bias pulses is applied to generate a high sheath voltage in the plasma sheath in contact with the top surface of the substrate in order to generate a vertically directed ion flux comprising high energy ions striking the top surface of the substrate. Each bias pulse of the plurality of bias pulses in the spike waveforms described above includes a triangular voltage spike having a high negative peak voltage. The voltage spike has a leading transition from a low positive base voltage to the peak voltage during a rise time and a trailing transition from the peak voltage to the base voltage during a rise time. The base voltage is a DC voltage applied for a base duration equal to the time between successive voltage spikes. The base duration, the rise time and the fall time are adjustable parameters that may be selected to obtain a narrow energy spread in the IEDF of the high energy ions compared to the energy spread obtainable by a rectangular pulsed waveform. One advantage of using triangular voltage spikes is that the leading transition of the triangular voltage allows current compensation along with increasing the sheath voltage. Another advantage of using triangular voltage spikes is that the spike waveforms may be generated using inexpensive standard waveform generation hardware. The method comprises adjusting the rise time to adjust the current compensation along with setting the high sheath voltage that accelerates ions to a high kinetic energy. Positive charges accumulating in the substrate during the leading transition are neutralized and the sheath voltage is reset during the fall time of trailing edge and a portion of the base duration. The base duration and the peak voltage may be adjusted independently to independently control the ion energy and the ion flux.

Example embodiments of the invention are described below. Other embodiments can also be understood from the entirety of the specification as well as the claims filed herein.

Example 1. A method for plasma processing a substrate includes: sustaining a plasma in a plasma processing chamber, the plasma processing chamber including a first electrode and a second electrode, where sustaining the plasma includes: coupling a source signal to the first electrode; and applying a bias signal to the second electrode, the bias signal having a spike waveform including a plurality of bias pulses, each of the bias pulses including a DC base voltage for a base duration and a triangular voltage spike having a rise time from the base voltage to a peak voltage and a fall time from the peak voltage to the base voltage, a sum of the rise time, the fall time, and the base duration including a pulse period, the applying including: independently adjusting the rise time and fall time to obtain a narrow energy spread of a mode at a high modal energy in an ion energy distribution function (IEDF) of an ion flux incident on the substrate, the narrow energy spread including a first width of the high energy mode of the IEDF that is smaller than a second width of the high energy mode of the IEDF obtainable using a rectangular pulse waveform.

Example 2. The method of example 1, where applying the bias signal further includes: changing the high modal energy of the IEDF independently from changing a magnitude of the ion flux by changing the peak voltage independently from changing the pulse period, where changing the pulse period includes changing the base duration.

Example 3. The method of one of examples 1 or 2, where the source signal includes a continuous wave radio frequency (RF) waveform, and where the plurality of bias pulses of the spike waveform includes a continuous train of bias pulses.

Example 4. The method of one of examples 1 to 3, where the source signal includes a continuous wave RF waveform, and where the plurality of bias pulses of the spike waveform is divided into a plurality of bursts, each burst including a concatenation of bias pulses, the bias signal having an ON state including the plurality of bursts and an OFF state between consecutive bursts.

Example 5. The method of one of examples 1 to 4, where the source signal includes a pulsed RF waveform including a plurality of RF pulses, the source signal having an ON state including the RF pulses and an OFF state with no RF power between consecutive RF pulses, and where the plurality of bias pulses of the spike waveform includes a continuous train of bias pulses.

Example 6. The method of one of examples 1 to 5, where the source signal includes a pulsed RF waveform including a plurality RF pulses, the source signal having an ON state including the RF pulses and an OFF state with no RF power between consecutive RF pulses, and where the plurality of bias pulses of the spike waveform is divided into a plurality of bursts, where each of the bursts includes a concatenation of bias pulses, the bias signal having an ON state including the plurality of bursts and an OFF state with no bursts between consecutive bursts.

Example 7. The method of one of examples 1 to 6, where the ON state of the source signal is in phase with the ON state of the bias signal, and where the OFF state of the source signal is in phase with the OFF state of the bias signal.

Example 8. The method of one of examples 1 to 7, where the ON state of the source signal is out of phase with the ON state of the bias signal, and where the OFF state of the source signal is out of phase with the OFF state of the bias signal.

Example 9. The method of one of examples 1 to 8, where the ON state of the source signal partially overlaps with the ON state of the bias signal, and where the OFF state of the source signal partially overlaps with the OFF state of the bias signal.

Example 10. A method for plasma processing a substrate includes: coupling a source signal to a first electrode of a plasma processing chamber; and applying a bias signal to a second electrode of the plasma processing chamber, the bias signal having a spike waveform including a plurality of bias pulses, each of the bias pulses including a DC base voltage for a base duration and a triangular voltage spike having a rise time from the base voltage to a peak voltage and a fall time from the peak voltage to the base voltage, a sum of the rise time, the fall time, and the base duration including a pulse period, the applying including: independently adjusting the rise time and fall time to obtain a narrow energy spread of a mode at a high modal energy in an ion energy distribution function (IEDF) of an ion flux incident on the substrate, the narrow energy spread including a first width of the high energy mode of the IEDF that is smaller than a second width of the high energy mode of the IEDF obtainable using a rectangular pulse waveform, where the plurality of bias pulses of the spike waveform includes a first plurality of first bias pulses having a first peak voltage and a second plurality of second bias pulses having a second peak voltage different from the first peak voltage.

Example 11. The method of example 10, where the bias signal includes an ON state including the plurality of bias pulses and an OFF state with no bias pulses.

Example 12. The method of one of examples 10 or 11, where the source signal includes a pulsed waveform including a plurality of source pulses, where the plurality of source pulses includes a first plurality of first source pulses having a first amplitude and a second plurality of second source pulses having a second amplitude different from the first amplitude.

Example 13. The method of one of examples 10 to 12, where the bias signal includes an ON state including the plurality of bias pulses and an OFF state with no bias pulses.

Example 14. The method of one of examples 10 to 13, where the source signal includes an ON state including the plurality of source pulses and an OFF state with no source pulses.

Example 15. The method of one of examples 10 to 14, where the first plurality of first source pulses is a plurality of first sinusoidal RF pulses and the second plurality of second source pulses is a plurality of second sinusoidal RF pulses.

Example 16. The method of one of examples 10 to 15, where the first plurality of first bias pulses is synchronized with the first plurality of first source pulses and the second plurality of second bias pulses is synchronized with the second plurality of second source pulses.

Example 17. The method of one of examples 10 to 16, where the first amplitude is larger than the second amplitude, and the first peak voltage is larger than the second peak voltage.

Example 18. The method of one of examples 10 to 17, where the first amplitude is larger than the second amplitude, and the first peak voltage is smaller than the second peak voltage.

Example 19. A plasma processing apparatus including: a plasma processing chamber to sustain a plasma, the plasma processing chamber including: a first electrode configured to receive a source signal; and a second electrode configured to receive a bias signal; a controller; and a memory coupled to the controller and storing instructions to be executed in the controller, the instructions when executed by the controller cause the apparatus to: couple the source signal from a first electrical circuit to the first electrode; and apply the bias signal from a second electrical circuit to the second electrode, the bias signal having a spike waveform including a plurality of bias pulses, each of the bias pulses including a pulse period and a voltage spike having a rise time from a base voltage to a peak voltage and a fall time from the peak voltage to the base voltage, where the instructions to apply includes instructions to change an ion energy of ions towards a pedestal independently from an ion flux toward the pedestal by independently changing the peak voltage from the pulse period.

Example 20. The method of example 19, where applying the bias signal further includes: changing an ion energy of ions incident on the substrate independently from an ion flux incident on the substrate by independently changing the peak voltage from the pulse period.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for plasma processing a substrate, the method comprising:
sustaining a plasma in a plasma processing chamber, the plasma processing chamber comprising a first electrode and a second electrode, wherein sustaining the plasma comprises:
coupling a source signal to the first electrode; and
applying a bias signal to the second electrode, the bias signal having a spike waveform comprising a plurality of bias pulses, each of the bias pulses comprising a DC base voltage for a base duration and a triangular voltage spike having a rise time from the base voltage to a peak voltage and a fall time from the peak voltage to the base voltage, a sum of the rise time, the fall time, and the base duration comprising a pulse period, the applying comprising:
independently adjusting the rise time and fall time to obtain a narrow energy spread of a mode at a high modal energy in an ion energy distribution function (IEDF) of an ion flux incident on the substrate, the narrow energy spread comprising a first width of the high energy mode of the IEDF that is smaller than a second width of the high energy mode of the IEDF obtainable using a rectangular pulse waveform.

2. The method of claim 1, wherein applying the bias signal further comprises:
changing the high modal energy of the IEDF independently from changing a magnitude of the ion flux by changing the peak voltage independently from changing the pulse period, wherein changing the pulse period comprises changing the base duration.

3. The method of claim 1, wherein the source signal comprises a continuous wave radio frequency (RF) waveform, and wherein the plurality of bias pulses of the spike waveform comprises a continuous train of bias pulses.

4. The method of claim 1, wherein the source signal comprises a continuous wave RF waveform, and wherein the plurality of bias pulses of the spike waveform is divided into a plurality of bursts, each burst comprising a concatenation of bias pulses, the bias signal having an ON state comprising the plurality of bursts and an OFF state between consecutive bursts.

5. The method of claim 1, wherein the source signal comprises a pulsed RF waveform comprising a plurality of RF pulses, the source signal having an ON state comprising the RF pulses and an OFF state with no RF power between consecutive RF pulses, and wherein the plurality of bias pulses of the spike waveform comprises a continuous train of bias pulses.

6. The method of claim 1, wherein the source signal comprises a pulsed RF waveform comprising a plurality RF pulses, the source signal having an ON state comprising the RF pulses and an OFF state with no RF power between consecutive RF pulses, and wherein the plurality of bias pulses of the spike waveform is divided into a plurality of bursts, wherein each of the bursts comprises a concatenation of bias pulses, the bias signal having an ON state comprising the plurality of bursts and an OFF state with no bursts between consecutive bursts.

7. The method of claim 6, wherein the ON state of the source signal is in phase with the ON state of the bias signal, and wherein the OFF state of the source signal is in phase with the OFF state of the bias signal.

8. The method of claim 6, wherein the ON state of the source signal is out of phase with the ON state of the bias signal, and wherein the OFF state of the source signal is out of phase with the OFF state of the bias signal.

9. The method of claim 6, wherein the ON state of the source signal partially overlaps with the ON state of the bias signal, and wherein the OFF state of the source signal partially overlaps with the OFF state of the bias signal.

10. A method for plasma processing a substrate, the method comprising:
coupling a source signal to a first electrode of a plasma processing chamber; and
applying a bias signal to a second electrode of the plasma processing chamber, the bias signal having a spike waveform comprising a plurality of bias pulses, each of the bias pulses comprising a DC base voltage for a base duration and a triangular voltage spike having a rise time from the base voltage to a peak voltage and a fall time from the peak voltage to the base voltage, a sum of the rise time, the fall time, and the base duration comprising a pulse period, the applying comprising:
independently adjusting the rise time and fall time to obtain a narrow energy spread of a mode at a high modal energy in an ion energy distribution function (IEDF) of an ion flux incident on the substrate, the narrow energy spread comprising a first width of the high energy mode of the IEDF that is smaller than a second width of the high energy mode of the IEDF obtainable using a rectangular pulse waveform, wherein the plurality of bias pulses of the spike waveform comprises a first plurality of first bias pulses having a first peak voltage and a second plurality of second bias pulses having a second peak voltage different from the first peak voltage.

11. The method of claim 10, wherein the bias signal comprises an ON state comprising the plurality of bias pulses and an OFF state with no bias pulses.

12. The method of claim 10, wherein the source signal comprises a pulsed waveform comprising a plurality of source pulses, wherein the plurality of source pulses comprises a first plurality of first source pulses having a first amplitude and a second plurality of second source pulses having a second amplitude different from the first amplitude.

13. The method of claim 12, wherein the bias signal comprises an ON state comprising the plurality of bias pulses and an OFF state with no bias pulses.

14. The method of claim 12, wherein the source signal comprises an ON state comprising the plurality of source pulses and an OFF state with no source pulses.

15. The method of claim 12, wherein the first plurality of first source pulses is a plurality of first sinusoidal RF pulses and the second plurality of second source pulses is a plurality of second sinusoidal RF pulses.

16. The method of claim 12, wherein the first plurality of first bias pulses is synchronized with the first plurality of first source pulses and the second plurality of second bias pulses is synchronized with the second plurality of second source pulses.

17. The method of claim 12, wherein the first amplitude is larger than the second amplitude, and the first peak voltage is larger than the second peak voltage.

18. The method of claim 12, wherein the first amplitude is larger than the second amplitude, and the first peak voltage is smaller than the second peak voltage.

19. A plasma processing apparatus comprising:
a plasma processing chamber to sustain a plasma, the plasma processing chamber comprising:
a first electrode configured to receive a source signal; and
a second electrode configured to receive a bias signal;
a controller; and
a memory coupled to the controller and storing instructions to be executed in the controller, the instructions when executed by the controller cause the apparatus to:
couple the source signal from a first electrical circuit to the first electrode; and
apply the bias signal from a second electrical circuit to the second electrode, the bias signal having a spike waveform comprising a plurality of bias pulses, each of the bias pulses comprising a pulse period and a voltage spike having a rise time from a base voltage to a peak voltage and a fall time from the peak voltage to the base voltage, wherein the instructions to apply comprises instructions to change an ion energy of ions towards a pedestal independently from an ion flux toward the pedestal by independently changing the peak voltage from the pulse period.

20. The method of claim 19, wherein applying the bias signal further comprises:
changing an ion energy of ions incident on the substrate independently from an ion flux incident on the substrate by independently changing the peak voltage from the pulse period.
